(19) United States
(12) Patent Application Publication
(10) Pub. No.: US 2012/0223416 A1
(43) Pub. Date: Sep. 6, 2012

(54) THIN-FILM SEMICONDUCTOR COMPONENT WITH PROTECTION DIODE STRUCTURE AND METHOD FOR PRODUCING A THIN-FILM SEMICONDUCTOR COMPONENT

(75) Inventors: Manfred Scheubeck, Horgau-Auerbach (DE); Siegfried Herrmann, Neukirchen (DE)

(73) Assignee: OSRAM Opto Semiconductors GmbH, Regensburg (DE)

(21) Appl. No.: 13/497,979

(22) PCT Filed: Nov. 11, 2010
(86) PCT No.: PCT/EP2010/067278

§ 371 Date: Apr. 25, 2012

(30) Foreign Application Priority Data
Nov. 13, 2009 (DE) 10 2009 053 064.9

(51) Int. Cl. H01L 29/861; H01L 21/02

(52) U.S. Cl. 257/603; 438/380; 257/E29.327; 257/E21.002

(57) ABSTRACT

A thin-film semiconductor component includes a carrier and a semiconductor body with a semiconductor layer sequence including an active region provided to generate radiation. The semiconductor body is externally electrically contactable by a first contact and a second contact. The carrier includes a protection diode structure connected electrically in parallel to the semiconductor body. The protection diode structure includes a first diode and a second diode. The first diode and the second diode are electrically connected in series in mutually opposing directions with regard to their forward direction.

### RELATED APPLICATIONS

This is a §371 of International Application No. PCT/EP2010/067278, with an international filing date of Nov. 11, 2010, which is based on German Patent Application No. 10 2009 053 064.9, filed Nov. 13, 2009, the subject matter of which is incorporated by reference.

### TECHNICAL FIELD

This disclosure relates to a thin-film semiconductor component with an active region provided to generate radiation, which region comprises a protection diode structure.

### BACKGROUND

In the case of optoelectronic semiconductor components, for example luminescent diode semiconductor chips, the risk often arises of their being damaged or even destroyed due to electrostatic discharge (ESD). To avoid such damage, protection diodes may be connected electrically in parallel to the radiation-generating diode, the forward directions of the protection diode and the radiation-generating diode being oriented antiparallel to one another.

Due to this interconnection, an electric current flows across the protection diode when a voltage is applied in the reverse direction to the radiation-generating diode. The current flowing across the protection diode makes it more difficult to determine the electrical characteristics of the radiation-emitting diode structure in the reverse direction. This in particular makes it more difficult to determine the polarity, i.e. the forward direction of the radiation-generating diode.

It could therefore be helpful to provide a semiconductor component which is protected from ESD damage and for which at the same time the polarity of the radiation-generating diode may be simply determined. It could also be helpful to provide a method for simplified production of such a semiconductor component.

### SUMMARY

We provide a thin-film semiconductor component including a carrier and a semiconductor body with a semiconductor layer sequence comprising an active region that generates radiation, wherein the semiconductor body is externally electrically contactable by a first contact and a second contact; the carrier includes a protection diode structure connected electrically in parallel to the semiconductor body; the protection diode structure includes a first diode and a second diode; and the first diode and the second diode are electrically connected in series in mutually opposing directions with regard to their forward direction.

We further provide a method for producing a plurality of thin-film semiconductor components including depositing a semiconductor layer sequence with an active region that generates radiation on a growth substrate; forming a plurality of semiconductor bodies from the semiconductor layer sequence; removing the growth substrate at least in selected places; providing a carrier assembly with a plurality of protection diode structures; positioning the plurality of semiconductor bodies relative to the carrier assembly such that at least one semiconductor body is associated with each protection diode structure; producing an electrically conductive connection between the semiconductor bodies and the protection diode structures; and finishing the plurality of semiconductor components, wherein one carrier is produced from the carrier assembly for each semiconductor component.

We still further provide a thin-film semiconductor component including a carrier and a semiconductor body with a semiconductor layer sequence including an active region that generates radiation, wherein the semiconductor body is externally electrically contactable by a first contact and a second contact; the semiconductor body includes a recess that extends from a side of the semiconductor body that faces the carrier through the active region; the carrier includes a protection diode structure connected electrically in parallel to the semiconductor body; the protection diode structure comprises a first diode and a second diode; and the first diode and the second diode are electrically connected in series in mutually opposing directions with regard to their forward direction.

### BRIEF DESCRIPTION OF THE DRAWINGS

FIGS. 1A and 1B are schematic sectional views of a first example of a semiconductor component.

FIGS. 2A and 2B show a second example of a semiconductor component in schematic plan view (FIG. 2B) and associated sectional view (FIG. 2A).

FIG. 3 shows a current-voltage characteristic for a semiconductor component according to the first example compared with a conventional component.

FIG. 4 is a schematic sectional view of a third example of a semiconductor component.

FIG. 5 is a schematic sectional view of a fourth example of a semiconductor component.

FIG. 6 is a schematic sectional view of a fifth example of a semiconductor component.

FIGS. 7A to 7C show an example of a method for producing a semiconductor component by intermediate steps shown in each case in schematic sectional view.

### DETAILED DESCRIPTION

Our thin-film semiconductor component may comprise a carrier and a semiconductor body with a semiconductor layer sequence. The semiconductor layer sequence comprises an active region provided to generate radiation. External electrical contact may be established for the semiconductor body by a first contact and a second contact. The carrier comprises a protection diode structure connected electrically in parallel to the semiconductor body. The protection diode structure comprises a first diode and a second diode. The first diode and the second diode are electrically connected in series in mutually opposing directions with regard to their forward direction.

The semiconductor body is protected from electrostatic discharge by the protection diode structure. An electrical voltage, arising for example as a result of electrostatic charging and applied in the reverse direction relative to the forward direction of the active region, may flow away via the protection diode structure. Damage to the semiconductor body is thus avoided.

A “thin-film semiconductor component” means in particular a semiconductor component in which a growth substrate for the semiconductor layer sequence of the semiconductor body is completely or at least partially removed or thinned.

A thin-film semiconductor component, which may in particular take the form of a thin-film light-emitting diode semiconductor chip, may be distinguished in particular by at least one of the following characteristic features:

on a first major surface, facing a carrier element, for example, the carrier of a semiconductor body comprising a semiconductor layer sequence with an active region, in particular of an epitaxial layer sequence, a mirror layer is applied or formed, for instance integrated as a Bragg mirror in the semiconductor layer, the mirror layer reflecting back into the semiconductor layer sequence at least some of the radiation generated in the sequence;

the semiconductor layer sequence has a thickness of 20 μm or less, in particular of 10 μm; and/or

the semiconductor layer sequence contains at least one semiconductor layer with at least one face which comprises an intermixing structure which ideally leads to an approximately ergodic distribution of the light in the semiconductor layer sequence, i.e. it exhibits scattering behavior which is as ergodically stochastic as possible.

The basic principle of a thin-film light-emitting diode chip is described for example in I. Schnitzer et al., Appl. Phys. Lett. 63 (16), 18 Oct. 1993, 2174-2176, the subject matter of which is incorporated herein by reference.

The carrier may comprise a first major face facing the semiconductor body and a second major face remote from the semiconductor body.

Preferably, the protection diode structure is integrated into the carrier. The protection diode structure may in particular be formed completely between the first major face and the second major face of the carrier. The two major faces of the carrier with the integrated protection diode structure may thus be of level construction. Attachment of the semiconductor body to the carrier is thereby simplified.

Further preferably, at least in the case of a voltage applied in the reverse direction of the semiconductor body, the protection diode structure exhibits a current-voltage characteristic in accordance with a Zener diode in the reverse direction. In particular, both the first diode and the second diode may be constructed in accordance with a Zener diode.

In other words, the current-voltage characteristic of the protection diode structure comprises a threshold value in the reverse direction of the active region. In the case of a voltage of a lower absolute value than the threshold value, there is no or at least no significant current flow through the protection diode structure.

The threshold value preferably amounts to at least 1 V, particularly preferably at least 2 V. In addition, the threshold value is preferably of a greater absolute value than a luminance threshold of the active region. A “luminance threshold” means a voltage value from which the semiconductor body displays measurable radiation emission. In other words, the threshold value is preferably at least of such an absolute value that the semiconductor component emits radiation in the case of a voltage corresponding to the threshold value in terms of the absolute value and applied in the forward direction of the semiconductor body.

When applying a test voltage which has a smaller absolute value than the threshold value, the thin-film semiconductor component thus exhibits a higher current flow in the forward direction than in the reverse direction relative to the active region despite integration of the protection diode structure. The polarity of the thin-film semiconductor component is thus simpler to determine.

Furthermore, the electrical characteristics of the active region of the semiconductor body may be tested by the test voltage applied in the reverse direction.

In other words, the protection diode structure may be configured such that, when the test voltage is applied, the thin-film semiconductor component behaves like a conventional semiconductor component without integrated protection diode. With a voltage having a greater absolute value than the threshold value, the protection diode structure on the other hand displays only comparatively low resistance such that, in the case of a voltage applied in the reverse direction which is of such absolute value that it could cause damage to the semiconductor component, current may flow through the protection diode structure.

Preferably, the first contact is formed a first contact layer, the first contact layer adjoining a first sub-region of the carrier. It is additionally preferable for the second contact to be formed by a second contact layer, the second contact layer adjoining a second sub-region of the carrier. Both the first contact and the second contact may thus in each case be connected electrically conductively with a sub-region of the carrier. At least one of the electrically conductive connections, preferably both electrically conductive connections, preferably display an ohmic or at least approximately ohmic current-voltage characteristic, i.e. a linear ratio of voltage to current.

The carrier is preferably based on a semiconductor material. Semiconductor materials are particularly suited to forming Zener diodes. Silicon is suitable in particular because of its broad application in electronics and its comparatively inexpensive and widespread availability.

The first sub-region and the second sub-region of the carrier are preferably of a first conduction type. The first sub-region and the second sub-region are thus of uniform conduction type. It is additionally preferable for a further region of the carrier to be formed between the first sub-region and the second sub-region, which further region is of a second conduction type different from the first conduction type of the first and second sub-regions. For example, the first sub-region and the second sub-region are n-conductive and the further region of the carrier is p-conductive, thereby resulting in an npn-structure. Alternatively, the carrier may also be inverted with regard to conduction type, thereby resulting in a pnp-structure. A junction between the first sub-region and the further region may form the first diode and a junction between the second sub-region and the further region may form the second diode of the protection diode structure.

Preferably, the first contact layer and/or the second contact layer are isolated electrically from the further region of the carrier by an insulation layer. The first contact layer and the second contact layer thus adjoin the carrier respectively only in the first sub-region or in the second sub-region thereof. The insulation layer may in particular comprise a first opening and a second opening which, in plan view of the semiconductor component, overlap respectively with the first sub-region or the second sub-region.

Further preferably, the first sub-region at least partially surrounds the second sub-region. In other words, the first sub-region may take the form of a frame and enclose the second sub-region at least in part.

Preferably, the semiconductor body is subdivided into a plurality of segments in a lateral direction, i.e. in a direction extending along a main plane of extension of the semiconductor layers of the semiconductor body. During production, these segments may be produced from a common semiconductor layer sequence for the semiconductor body.

The segments of the semiconductor body may be externally electrically contactable at least partially independently of one another. In particular, at least one, in particular separate, protection diode structure may be associated with each of the mutually independently externally electrically contactable segments. Accordingly, the semiconductor body comprises a plurality of segments each protected from ESD damage.

Alternatively, the segments of the semiconductor body are at least partially electrically interconnected in series. In this case, the series-connected segments may comprise a common protection diode structure connected electrically in parallel to the series of segments.

There is a wide range of freely selectable arrangements of the contacts via which, when the semiconductor component is in operation, charge carriers may be injected from different sides into the active region of the semiconductor body and recombine there with the emission of radiation.

At least one of the contacts may be arranged on the side of the carrier remote from the semiconductor body. The semiconductor body may in this case be electrically conductively connected with the contact through at least one opening into the carrier.

Alternatively or in addition, at least one of the contacts may be arranged on the side of the carrier facing the semiconductor body. In particular, both contacts may be arranged on the side of the carrier facing the semiconductor body. The semiconductor component is thus contactable at the front, the front being understood to mean in particular that side from which the majority of the radiation generated in the active region exits the semiconductor component.

In a method for producing a plurality of semiconductor components, a semiconductor layer sequence with an active region provided for generating radiation may be deposited on a growth substrate. A plurality of semiconductor bodies are formed from the semiconductor layer sequence. The growth substrate is removed at least in places. A carrier assembly with a plurality of protection diode structures is provided. A plurality of semiconductor bodies are positioned relative to the carrier assembly such that at least one semiconductor body is associated with each protection diode structure. An electrically conductive connection of the semiconductor bodies with the protection diode structures is produced. The plurality of semiconductor components are finished, one carrier being produced from the carrier assembly for each semiconductor component.

The method steps do not necessarily have to be performed in the sequence listed above.

The protection diode structure may thus already be formed in the carrier before the semiconductor bodies are attached to the respectively associated carrier.

An electrical connection to the respective protection diode structure is thus produced as early as with connection of the semiconductor bodies to the respective carrier such that the semiconductor bodies are protected from damage by electrostatic discharge at an early stage of production, in particular as early as prior to formation of the semiconductor components from the carrier assembly.

Preferably, removal at least in places of the growth substrate takes place after production of the electrically conductive connection between the semiconductor bodies and the protection diode structure. The growth substrate may thus serve in mechanical stabilization of the semiconductor bodies until attachment of the semiconductor bodies to the carrier assembly. After attachment, mechanical stabilization of the semiconductor bodies is no longer necessary such that the growth substrate may be removed.

In contrast thereto, the growth substrate removal may however also proceed prior to production of an electrically conductive connection between the semiconductor bodies and the protection diode structures.

The above-described method is suitable in particular for the production of semiconductor components constructed as described further above. Features listed in connection with the semiconductor component may therefore also be used for the method and vice versa.

Further features, configurations and convenient aspects are revealed by the following description of examples in conjunction with the figures.

Identical, similar or identically acting elements are provided with identical reference numerals in the figures. The figures are in each case schematic representations and are therefore not necessarily true to scale. Rather, comparatively small elements and in particular layer thicknesses may be illustrated on an exaggeratedly large scale for clarification.

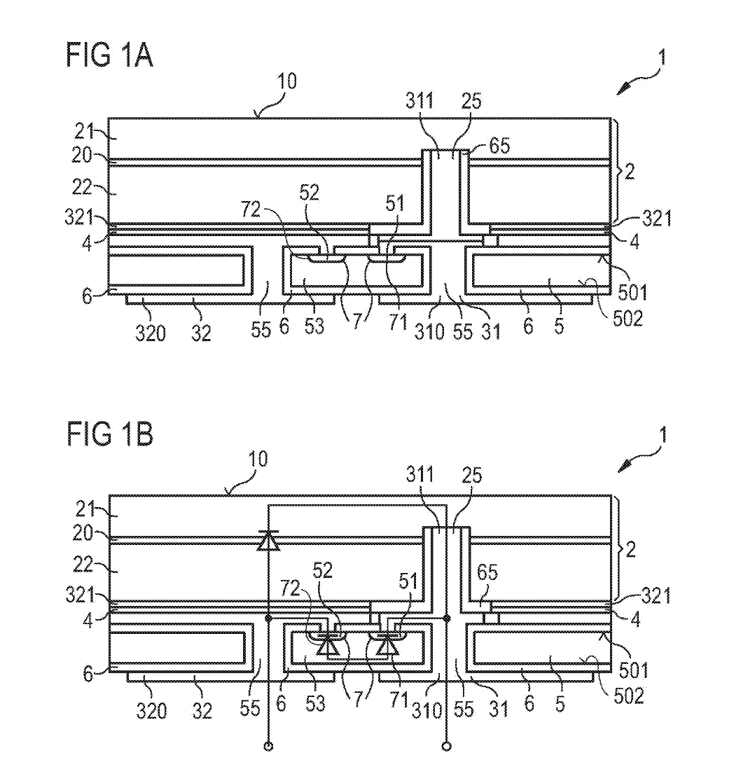

FIG. 1A shows a first example of a semiconductor component 1 which takes the form of a thin-film LED semiconductor chip. The semiconductor component 1 comprises a semiconductor body 2 with a semiconductor layer sequence which forms the semiconductor body. A growth substrate for the semiconductor layer sequence has been completely removed. The semiconductor layer sequence comprises an active region 20 arranged between a first semiconductor layer 21 and a second semiconductor layer 22. The first semiconductor layer and the second semiconductor layer are conveniently different from one another with regard to conduction type such that they form a diode structure.

The semiconductor body 2 is arranged on a carrier 5 and connected mechanically stably thereto. Connection proceeds by a bonding layer 4 arranged between a first major face 501 of the carrier 5 facing the semiconductor body 2 and the semiconductor body 2.

An example of a suitable bonding layer is a solder layer or an, in particular electrically conductive, adhesive layer.

The carrier 5 comprises a first sub-region 51 and a second sub-region 52 which are each of the same conduction type. The sub-regions may for example each be n-conductive. The carrier 5 furthermore comprises a further region 53 extending between the first sub-region and the second sub-region and of a second conduction type different from the first conduction type. A pn-junction thus arises in each case between the first sub-region 51 and the further region 53 and between the second sub-region 52 and the further region 53. The first diode 71 or second diode 72 formed thereby form a protection diode structure 7 in which the first diode and the second diode are electrically connected in series in mutually opposing directions with regard to their forward direction. Furthermore, the semiconductor component comprises a first contact 31 and a second contact 32 provided in each case for electrical external contacting of the semiconductor component 1. In the example shown, the first contact and the second contact are each formed on the second major face 502 of the carrier remote from the semiconductor body 2. The semiconductor component is thus electrically contactable from a side remote from the radiation exit face 10 of the semiconductor component.

The first contact 31 and the second contact 32 are each formed by a first contact layer 310 or a second contact layer 320, respectively. The contact layer 310 adjoins the first sub-region 51 of the carrier 5. The second contact layer 320 of the second contact 32 additionally adjoins the second sub-region 52 of the carrier.

The first sub-region 51 and the second sub-region 52 may also be configured such that the first sub-region surrounds the second sub-region, in particular completely (not shown explicitly).

The semiconductor body comprises a recess 25 extending from the side of the semiconductor body facing the carrier 5 through the active region 20.

The semiconductor body 2 comprises just one recess 25 to simplify representation. The higher the number of recesses, the more uniformly charge carriers may be injected laterally via the first semiconductor layer 21 into the active region such that the radiation may exit comparatively homogeneously from the radiation exit face 10.

In the recess 25, a first connection layer 311 is formed via which the first semiconductor layer 21 is electrically conductively connected to the first contact 31. Furthermore, to prevent electrical short circuits, the first connection layer 311 is electrically insulated in the recess 25 from the active region 20 and the second semiconductor layer 22 by a further insulation layer 65.

On the side of the semiconductor body 2 facing the carrier 5, the second semiconductor layer 22 comprises a second connection layer 321 via which the second semiconductor layer 22 is electrically conductively connected to the second contact 32.

The first connection layer and/or the second connection layer preferably contain a metal or consist of a metal, for example Ag, Rh, Ti, Pt, Pd, Au or Al, or contain a metal alloy with at least one of those stated metals. The metals may also be used for the contact layer 310 and/or the second contact layer 320.

The semiconductor body 2, in particular the active region 20, preferably comprises a Group III-V semiconductor material.

Group III-V-semiconductor materials are particularly suitable for generating radiation in the ultraviolet (InₓGa_{y}Al_{1-x-y}N) through the visible (InₓGa_{y}Al_{1-x-y}N, in particular for blue to green radiation, or InₓGa_{y}Al_{1-x-y}P, in particular for yellow to red radiation) to the infrared (InₓGa_{y}Al_{1-x-y}As) range of the spectrum. In each case 0≦x≦1, 0≦y≦1 and x+y≦1 applies, in particular with x≠1, y≠1, x≠0 and/or y≠0. Using Group III-V semiconductor materials, in particular from the stated material systems, it is additionally possible to achieve high internal quantum efficiencies in the generation of radiation.

The carrier 5 preferably contains a semiconductor material or consists of a semiconductor material. Silicon is particularly suitable as carrier material, in particular due to silicon technology being well established and its comparatively inexpensive availability. Another semiconductor material, for example Ge or GaAs, may however also be used.

The carrier 5 further comprises openings 55 extending from the first major face 501 as far as the second major face 502 of the carrier opposite the first major face. The semiconductor body is electrically contactable via these openings from the side of the carrier remote from the semiconductor body.

An insulation layer 6 is arranged between the further region 53 of the carrier and the first contact layer 310 as well as the second contact layer 320. The first contact 31 and the second contact 32 are thus in each case connected electrically conductively with the carrier by an ohmic connection only via the first sub-region or the second sub-region 51 or 52, respectively. To this end, the insulation layer 6 comprises openings in which the contact layers 310, 320 adjoin the carrier 5.

The insulation layer 6 and/or the further insulation layer 65 preferably contain an oxide, for example silicon oxide or titanium oxide, a nitride, for example silicon nitride, or an oxynitride, for example silicon oxynitride, or consist of such a material.

The current paths within the semiconductor component 1 are illustrated schematically in FIG. 1B. In this case, the first semiconductor layer 21 is by way of example n-conductive and the second semiconductor layer 22 accordingly p-conductive. The first and second sub-regions 51 or 52 respectively of the carrier 5 are in each case n-conductive, the further region 53 of the carrier being p-conductive.

On application of a positive voltage to the second contact 32 relative to the first contact 31, the active region 20 is operated in the forward direction such that charge carriers are injected from different sides via the first semiconductor layer 21 and the second semiconductor layer 22 into the active region and recombine there with radiation emission. In the case of a voltage applied in the reverse direction, the latter may flow away via the protection diode structure 7. The first diode 71 and the second diode 72 each take the form of Zener diodes such that in the case of a voltage applied in the reverse direction, a significant current flows across the protection diode structure only from a given threshold value. In the case of a voltage which has a greater absolute value than the voltage of the threshold value, the protection diode structure thus exhibits only comparatively low resistance such that in the case of electrostatic charging the charge carriers may flow away via the protection diode structure and the risk of damage to the semiconductor body may thereby be very largely avoided.

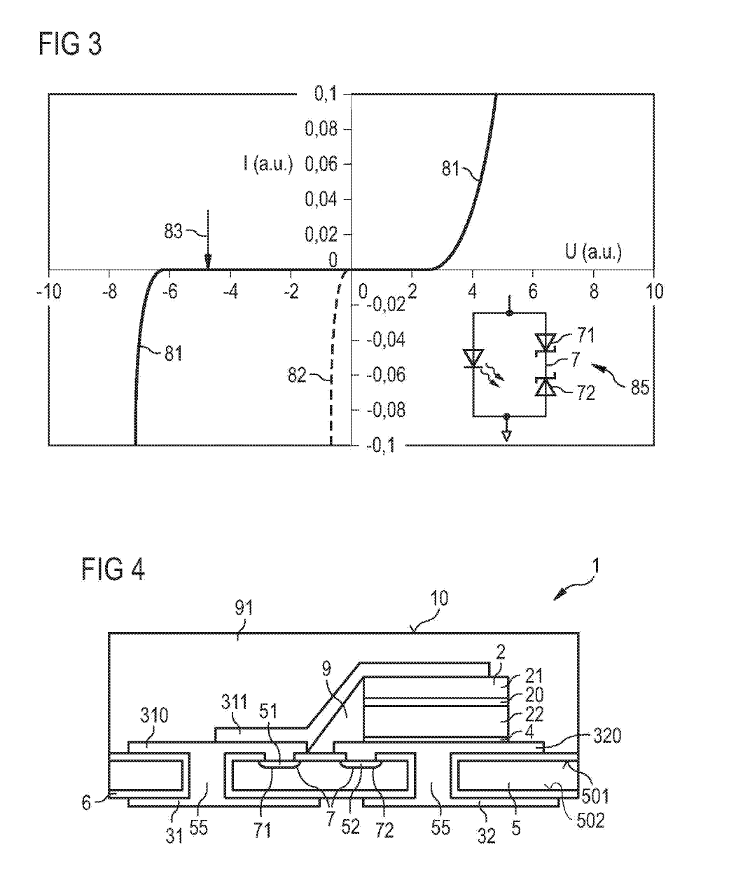

A corresponding current-voltage characteristic is illustrated schematically in FIG. 3, wherein a curve 81 illustrates the current I as a function of the applied voltage U for a semiconductor component according to the first example, the voltage and the current each being stated in arbitrary units. In comparison thereto, the curve 82 shows a current-voltage characteristic for a conventional component, in which a single protection diode is connected antiparallel to the active region. In contrast to the curve 81, this curve exhibits a comparatively low resistance even in the case of negative voltages of comparatively low absolute value. With a conventional component, in the case of a test voltage as illustrated in FIG. 3 by an arrow 83, a very high current would thus also flow in the reverse direction of the active region such that it would be impossible or difficult to determine the polarity of the semiconductor component.

In contrast, in the case of a protection diode structure with two Zener diodes connected in mutually opposing directions with regard to their forward direction, no or at least no significant current may flow across the protection diode structure with the test voltage such that it is simple to determine the polarity of the component despite the integration of a protection diode structure.

In the case of voltages of high absolute value applied in the reverse direction of the semiconductor body 20, the resistance of the protection diode structure 7 is nevertheless so low that the semiconductor component is efficiently protected from damage due to electrostatic discharge by the integrated protection diode structure.

Furthermore, FIG. 3 shows an equivalent circuit diagram 85 for the protection diode structure 7 with the first diode 71 and the second diode 72, the protection diode structure being connected electrically in parallel to the active region 20.

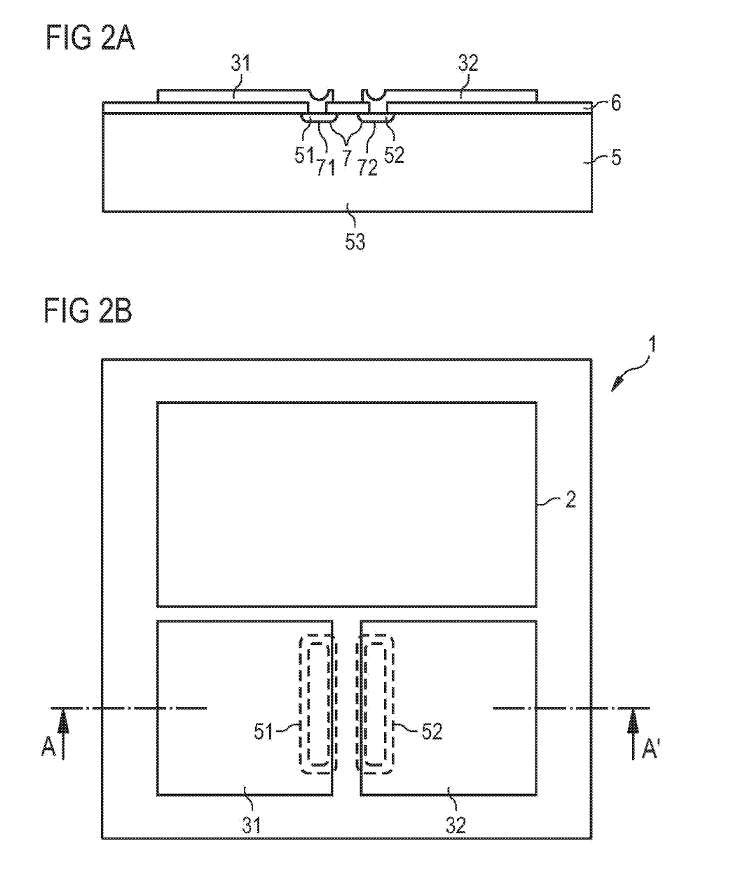

A second example of a semiconductor component is shown in schematic plan view and in schematic sectional view along line AA′ in FIGS. 2A and 2B.

Unlike in the first example, the contacts 31 and 32 are each arranged on the side of the carrier 5 facing the semiconductor body 2. The carrier 5 may thus be free of openings 55.

The first contact 31, the second contact 32 and the semiconductor body 2 are thus arranged laterally adjacent one another.

It goes without saying that one of the contacts may also be arranged on the side of the carrier facing the semiconductor body 2 and the other contact on the side of the carrier remote from the semiconductor body and, as described in connection with the first example, connected to the semiconductor body via openings through the carrier.

A third example of a semiconductor component is illustrated schematically in sectional view in FIG. 4. Unlike in the first example, the semiconductor body 2 does not comprise any recesses 25. To connect the first semiconductor layer 21 electrically conductively with the first contact 31, the first connection layer 311 extends beyond the top of the first semiconductor layer 21 and via a slope to the first contact layer 310. The slope is formed by a planarization layer 9 which electrically isolates the first connection layer simultaneously from the active region 20 and the second semiconductor layer 22. The planarization layer is conveniently of electrically insulating construction. The planarization layer may for example contain BCB (benzocyclobutene), silicon oxide or silicon nitride or consist of such a material.

Furthermore, the semiconductor component 1 comprises an encapsulation 91 which in particular protects the semiconductor body 2 from mechanical damage and/or adverse external environmental influences, for instance moisture.

FIG. 5 is a schematic sectional view of a fourth example of a semiconductor component, this semiconductor component being constructed substantially like the one described in connection with FIG. 1.

In contrast thereto, the semiconductor body 2 comprises a plurality of segments. In this example, just two segments 2A and 2B being shown by way of example. During production of the semiconductor component, the segments are produced from a common semiconductor layer sequence for the semiconductor body 2. For example, the segments may be isolated electrically from one another by a wet chemical and/or dry chemical etch step.

As described in connection with FIG. 1, the segments of the semiconductor body are externally electrically contactable via a first contact 31 and a second contact 32. The segments may thus be externally electrically actuated independently of one another. The segments may for example be configured in the manner of a matrix to form an image display device.

A protection diode structure 7 is associated with each of the segments 2A and 2B, which structure, as described in connection with FIG. 1, is formed in the carrier. Each segment of the semiconductor body is thus provided individually by a protection diode structure and nonetheless may be simply tested in the reverse direction in terms of its electrical characteristics.

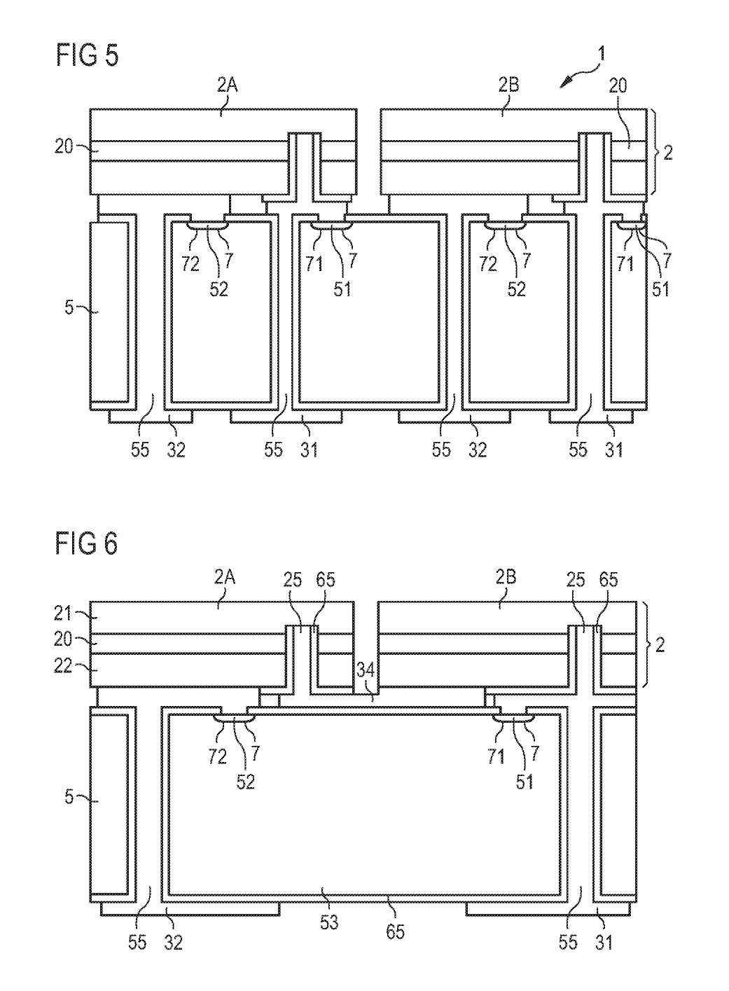

A sixth example of a semiconductor body is illustrated schematically in sectional view in FIG. 6. This example substantially corresponds to the fourth example described in connection with FIG. 5. In contrast thereto, the segments of the semiconductor body 2A, 2B are electrically interconnected in series. Furthermore, a common protection diode structure 7 is associated with the segments 2A, 2B. Interconnection of the segments in series proceeds by a further connection layer 34. The further connection layer results in an electrically conductive connection of the first semiconductor layer 21 of the segment 2A through the recess 25 to the second semiconductor layer 22 of the second segment 2B of the semiconductor body 2. One of the materials mentioned in relation to the first and second connection layers is particularly suitable for the further connection layer.

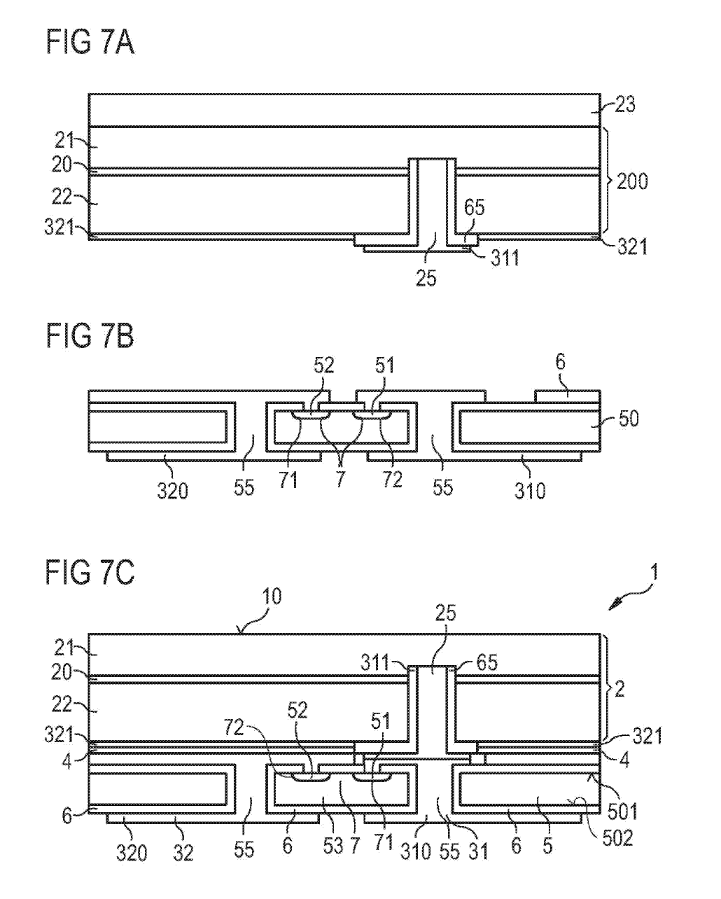

An example of a method for producing a semiconductor component is shown in FIGS. 7A to 7C by way of intermediate steps each shown in schematic sectional view.

Production is shown merely by way of example for a semiconductor component configured in accordance with the first example described in connection with FIG. 1A. Moreover, to simplify representation just one semiconductor component is shown. It goes without saying that the method may be used for the simultaneous production of a plurality of semiconductor components.

A semiconductor layer sequence 200 with an active region 20, a first semiconductor layer 21 and a second semiconductor layer 22 is deposited on a growth substrate, preferably epitaxially, for example by MOCVD or MBE. From the side remote from the growth substrate a recess 25 is formed in the semiconductor layer sequence, which recess extends through the active region 20 into the first semiconductor layer 21. This may take place for example by wet chemical or dry chemical etching. A further insulation layer 65 which covers the side faces of the recess 25 is formed in the region of the recess 25. On the further insulation layer 65 a first connection layer 311 is formed which is electrically conductively connected with the first semiconductor layer 21. Furthermore, a second connection layer 321 is deposited on the second semiconductor layer 22, for example by vapor deposition or sputtering.

FIG. 7B shows part of a carrier assembly 50 from which a carrier 5 is produced for the semiconductor chip.

The carrier 5 comprises openings 55 through which a first contact layer 310 and a second contact layer 320 respectively extend.

As described in connection with FIG. 1A, a first sub-region 51, a second sub-region 52 and a further region 53 are formed in the carrier, these forming a protection diode structure 7 with two Zener diodes. The protection diode structure is electrically contactable via the first contact layer 310 and the second contact layer 320.

The protection diode structure is thus already formed on the carrier assembly before the semiconductor bodies are attached to the carrier.

The semiconductor body 2 is positioned relative to the carrier such that electrical contact may be produced between the first contact layer 310 and the first connection layer 311 or the second contact layer 320 and the second connection layer 321. This connection is produced by a bonding layer 4, for instance a solder layer or an electrically conductive adhesive layer.

After attachment of the semiconductor bodies 2, the growth substrate 23 is no longer needed for mechanical stabilization of the semiconductor body and may thus be removed. As a result of the protection diode structure integrated into the carrier, the semiconductor body may thus be protected from ESD damage as early as during removal of the growth substrate.

Alternatively, the growth substrate may even be removed before the semiconductor bodies are attached to the carrier 5. In this case, the semiconductor bodies 2 are preferably attached to an auxiliary carrier which may be removed after bonding of the semiconductor bodies to the carrier.

Removal of the growth substrate may proceed for example mechanically, for instance by grinding, lapping or polishing, and/or chemically, for example by wet chemical or dry chemical etching and/or by coherent radiation, in particular laser radiation.

A finished semiconductor component constructed as described in connection with FIG. 1A, is shown in FIG. 7C. Singulation of the carrier assembly into a plurality of carriers 5 with in each case at least one semiconductor body 2 may proceed for example mechanically, for instance by cleaving, scribing or breaking and/or by coherent radiation, in particular laser radiation. Singulation of the carrier assembly thus results in semiconductor components which have the protection diode structure already integrated in them.

This disclosure is not restricted by the description given with reference to the examples. Rather, our components and methods encompass any novel feature and any combination of features, including in particular any combination of features in the appended claims, even if the feature or combination is not itself explicitly indicated in the claims or the examples.

1.-16. (canceled)

17. A thin-film semiconductor component comprising:
a carrier; and
a semiconductor body with a semiconductor layer sequence comprising an active region that generates radiation,
wherein the semiconductor body is externally electrically contactable by a first contact and of a second contact;
the carrier comprises a protection diode structure connected electrically in parallel to the semiconductor body;
the protection diode structure comprises a first diode and a second diode; and
the first diode and the second diode are electrically connected in series in mutually opposing directions with regard to their forward direction.

18. The semiconductor component according to claim 17, wherein the protection diode structure is integrated into the carrier.

19. The semiconductor component according to claim 17, wherein, when a voltage applied in a reverse direction of the semiconductor body, the protection diode structure comprises a current-voltage characteristic in accordance with a Zener diode in the reverse direction.

20. The semiconductor component according to claim 17, wherein a growth substrate for the semiconductor layer sequence of the semiconductor body is removed.

21. The semiconductor component according to claim 17, wherein the first contact is formed by a first contact layer and the second contact by a second contact layer; the first contact layer adjoins a first sub-region and the second contact layer adjoins a second sub-region of the carrier; and the carrier is based on a semiconductor material, wherein the first sub-region and the second sub-region of the carrier are of a first conduction type and a further region of the carrier is formed between the first sub-region and the second sub-region, which further region is of a second conduction type different from the first conduction type.

22. The semiconductor component according to claim 21, wherein the first contact layer and the second contact layer are electrically isolated from the further region of the carrier by an insulation layer.

23. The semiconductor component according to claim 21, wherein the first sub-region at least partially surrounds the second sub-region.

24. The semiconductor component according to claim 17, wherein the semiconductor body is subdivided in a lateral direction into a plurality of segments.

25. The semiconductor component according to claim 24, wherein the segments of the semiconductor body are externally electrically contactable at least partially independently of one another, and at least one protection diode structure is associated with each of the mutually independently externally electrically contactable segments.

26. The semiconductor component according to claim 24, wherein the segments of the semiconductor body are at least partially electrically interconnected in series.

27. The semiconductor component according to claim 17, wherein at least one of the contacts is arranged on the side of the carrier remote from the semiconductor body, and the semiconductor body is electrically conductively connected to the contact through at least one opening in the carrier.

28. The semiconductor component according to claim 17, wherein at least one of the contacts is arranged on a side of the carrier facing the semiconductor body.

29. A method for producing a plurality of thin-film semiconductor components comprising:
a) depositing a semiconductor layer sequence with an active region that generates radiation on a growth substrate;
b) forming a plurality of semiconductor bodies from the semiconductor layer sequence;
c) removing the growth substrate at least in selected places;
d) providing a carrier assembly with a plurality of protection diode structures;
e) positioning the plurality of semiconductor bodies relative to the carrier assembly such that at least one semiconductor body is associated with each protection diode structure;
f) producing an electrically conductive connection between the semiconductor bodies and the protection diode structures; and
g) finishing the plurality of semiconductor components, wherein one carrier is produced from the carrier assembly for each semiconductor component.

30. The method according to claim 29, wherein step c) is performed after step f).

31. A thin-film semiconductor component comprising:
a carrier; and
a semiconductor body with a semiconductor layer sequence comprising an active region that generates radiation,
wherein the semiconductor body is externally electrically contactable by a first contact and a second contact;
the semiconductor body comprises a recess that extends from a side of the semiconductor body that faces the carrier through the active region;
the carrier comprises a protection diode structure connected electrically in parallel to the semiconductor body;
the protection diode structure comprises a first diode and a second diode; and
the first diode and the second diode are electrically connected in series in mutually opposing directions with regard to their forward direction.

32. The semiconductor component according to claim 31, wherein a growth substrate for the semiconductor layer sequence of the semiconductor body is removed.
